(19) United States
(12) Patent Application Publication
(10) Pub. No.: US 2023/0361193 A1
(43) Pub. Date: Nov. 9, 2023

(54) JUNCTION STRUCTURE ELEMENT AND METHOD OF MANUFACTURING THE SAME

(71) Applicant: RESEARCH & BUSINESS FOUNDATION SUNGKYUNKWAN UNIVERSITY, Suwon-si (KR)

(72) Inventors: Sung Joo LEE, Seongnam-si (KR); Sung Pyo BAEK, Suwon-si (KR); Hyun Ho YOO, Suwon-si (KR); Su Min JEON, Suwon-si (KR); Jingjie NIU, Suwon-si (KR)

(73) Assignee: RESEARCH & BUSINESS FOUNDATION SUNGKYUNKWAN UNIVERSITY, Suwon-si (KR)

(21) Appl. No.: 18/142,600

(22) Filed: May 3, 2023

(30) Foreign Application Priority Data
May 3, 2022 (KR) 10-2022-0054606

(51) Int. Cl. H01L 29/51; H10B 51/30; H01L 29/66; H01L 29/78; H01L 29/417

(52) U.S. Cl. CPC H01L 29/516; H10B 51/30; H01L 29/6684; H01L 29/78391; H01L 29/41725

(57) ABSTRACT

Provided are a junction structure element and a method of manufacturing the junction structure element. The junction structure element includes a semiconductor channel layer which includes a material having ferroelectric and semiconductor properties, a source electrode and a drain electrode which are each in contact with the semiconductor channel layer and are spaced apart from each other, a ferroelectric layer which is formed on the semiconductor channel layer and includes a material having ferroelectric properties, and a gate electrode to be disposed on the ferroelectric layer. The method of manufacturing the junction structure element includes a first operation of forming a semiconductor channel layer, which includes a material having ferroelectric and semiconductor properties, on a substrate, and a second operation of forming a ferroelectric layer, which includes a material having ferroelectric properties, on the semiconductor channel layer.

### CROSS-REFERENCE TO RELATED APPLICATIONS

This application claims the priority benefit of Korean Patent Application No. 10-2022-0054606 filed on May 3, 2022, in the Korean Intellectual Property Office, the disclosures of which are incorporated herein by reference.

### BACKGROUND

### 1. Field

The present invention relates to a junction structure element and a method of manufacturing the same.

### 2. Description of the Related Art

Ferroelectric materials or ferroelectrics are materials which are spontaneously polarized without an external electric field and of which a polarization direction is changeable by an external electric field. Two-dimensional semiconductors such as α-In₂Se₃-based ferroelectric elements have advantages in that, due to a crystal structure thereof, stability is high and polarization is directly controllable. However, due to a limitation on an amount of polarization in a two-dimensional structure, there are problems that an on/off ratio (<10⁴) is low and a retention time (500 s) is short. Meanwhile, when used to constitute ferroelectric elements, ferroelectric insulators having an amorphous structure have limitations such as a leakage current, inefficiency in polarization control characteristics due to an indirect control structure of a channel, and instability of material characteristics due to an amorphous structure. Therefore, there is a need to develop a method capable of stably controlling polarization characteristics by overcoming such disadvantages of ferroelectric semiconductors and ferroelectric insulators, and a device in which the method is implemented.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

The present invention is directed to providing a junction structure element based on a ferroelectric material in which polarization characteristics are stably controllable.

The present invention is also directed to providing a method of manufacturing the element.

The present invention is also directed to providing a computing device including the element.

According to an aspect of the present invention, there is provided a junction structure element including a semiconductor channel layer which includes a material having ferroelectric and semiconductor properties, a source electrode and a drain electrode which are each in contact with the semiconductor channel layer and are spaced apart from each other, a ferroelectric layer which is formed on the semiconductor channel layer and includes a material having ferroelectric properties, and a gate electrode disposed on the ferroelectric layer.

The junction structure element may further include an insulating layer which is disposed between the semiconductor channel layer and the ferroelectric layer and includes a material having insulating properties.

The insulating layer may have a thickness of 5 nm to 10 nm.

The insulating layer may include h-BN.

The semiconductor channel layer and the ferroelectric layer may include at least one material each independently differently selected from the group consisting of graphanol, hydroxyl-functionalized graphene, halogen-decorated phosphorene, g-C₆N₈H, Bi—CH₂OH and two-dimensional perovskite including arsenic (As), antimony (Sb), bismuth (Bi), tellurium (Te), d1T-MoS₂, t-MoS₂, WS₂, WSe₂, WTe₂, BiN, SbN, BiP, α-In₂Se₃, GaN, GaSe, SiC, BN, AlN, ZnO, GeS, GeSe, SnS, SnSe, SiTE, GeTe, SnTE, PbTe, CrN, CrB₂, CrBr₃, CrI₃, GaTeCl, AgBiP₂Se₆, CuCrP₂S₆, CuCrP₂Se₆, CuVP₂S₆, CuVP₂Se₆, CuInP₂Se₆, CuInP₂S₆(CIPS), Sc₂CO₂, Bi₂O₂Se, Bi₂O₂Te, Bi₂O₂S, Ba₂PbCl₄.

The semiconductor channel layer may include α-In₂Se₃ or SnS, and the ferroelectric layer may include CIPS.

A voltage applied between the source electrode and the drain electrode may adjust a degree of polarization in the horizontal direction of the semiconductor channel layer, and a voltage applied to the gate electrode may adjust a degree of polarization in the vertical direction of the ferroelectric layer.

An increasing or decreasing state of a current conducted in the semiconductor channel layer may be determined according to an increasing or decreasing state of a current applied between the source electrode and the drain electrode and an increasing or decreasing state of a current applied to the gate electrode.

Current conductivity of the semiconductor channel layer may be determined according to a pulse of the voltage applied between the source electrode and the drain electrode and a pulse of the voltage applied to the gate electrode.

The semiconductor channel layer may have a thickness of 40 nm to 60 nm, and the ferroelectric layer may have a thickness of 60 nm to 100 nm.

The source electrode, the drain, and the gate electrode may each include at least one material selected from the group consisting of titanium (Ti) and gold (Au).

According to another aspect of the present invention, there is provided a method of manufacturing a junction structure element, the method including a first operation of forming a semiconductor channel layer, which includes a material having ferroelectric and semiconductor properties, on a substrate, a second operation of forming a ferroelectric layer, which includes a material having ferroelectric properties, on the semiconductor channel layer, and an electrode forming operation of forming a source electrode and a drain electrode each in contact with the semiconductor channel layer and spaced apart from each other, and forming a gate electrode disposed on the ferroelectric layer.

The method may further include, after the first operation, an insulating layer forming operation of forming an insulating layer, which includes a material having insulating properties, on the semiconductor channel layer, wherein, in the second operation, the ferroelectric layer is formed on the insulating layer.

The semiconductor channel layer, the ferroelectric layer, and the insulating layer may be formed through dry transferring.

### BRIEF DESCRIPTION OF THE DRAWINGS

These and/or other aspects of the disclosure will become apparent and more readily appreciated from the following description of the embodiments, taken in conjunction with the accompanying drawings of which:

FIGS. 1 and 2 are schematic diagrams illustrating an example of a junction structure element according to an embodiment of the present invention.

FIGS. 3 and 4 are flowcharts illustrating an example of a method of manufacturing a junction structure element according to an embodiment of the present invention.

FIG. 5 is a diagram illustrating a configuration of a computing device according to an embodiment of the present invention.

FIG. 6A-D, 7A-B, 8A-F, 9A-F, 10A-10C, 11A-E, 12, 13A-B, 14A-B, 15A-C, 16, 17A-D, 18 A-D, and 19A-E are views showing results according to experimental examples of the present invention.

Throughout the drawings and the detailed description, the same reference numerals may refer to the same, or like, elements. The drawings may not be to scale, and the relative size, proportions, and depiction of elements in the drawings may be exaggerated for clarity, illustration, and convenience.

### DETAILED DESCRIPTION

Hereinafter, embodiments of the present invention will be described in detail with reference to the accompanying drawings. While the present invention is open to various modifications and alternative embodiments, specific embodiments thereof will be described and illustrated by way of example in the accompanying drawings. However, this is not purported to limit the present invention to a specific disclosed form, but it shall be understood to include all modifications, equivalents, and substitutes within the idea and the technological scope of the present invention. Like numbers refer to like elements throughout the description of the drawings. In the accompanying drawings, the dimensions of structures may be exaggerated to clarify the described technology.

The terminology used in this application is for the purpose of describing particular embodiments only and is not intended to be limiting of the invention. A singular expression includes a plural expression unless the context clearly indicates otherwise. In this application, it should be understood that terms such as “include” or “have” are intended to indicate that there is a feature, number, step, operation, component, or a combination thereof described on the specification, and they do not exclude in advance the possibility of the presence or addition of one or more other features or numbers, steps, operations, components, or combinations thereof.

Unless defined otherwise, all the terms (including technical and scientific terms) used herein have the same meaning as commonly understood by one of ordinary skill in the art to which the present invention belongs. It will further be understood that the terms, such as those defined in commonly used dictionaries, should be interpreted as having meanings that are consistent with their meanings in the context of the relevant art and should not be interpreted in an idealized or overly formal sense unless expressly defined otherwise herein.

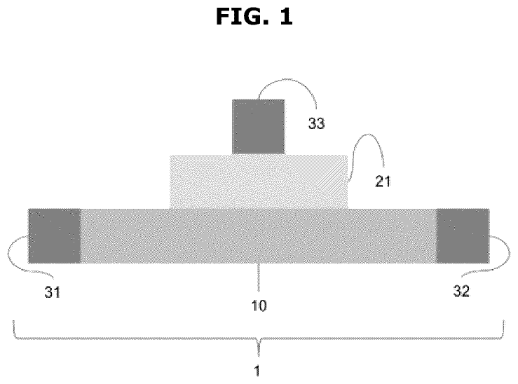

FIG. 1 is a schematic diagram illustrating an example of a junction structure element according to an embodiment of the present invention.

Referring to FIG. 1, a junction structure element 1 according to the embodiment of the present invention may include a semiconductor channel layer 10 which includes a material having ferroelectric and semiconductor properties, a source electrode 31 and a drain electrode 32 which are each in contact with the semiconductor channel layer 10 and are spaced apart from each other, a ferroelectric layer 21 which is formed on the semiconductor channel layer and includes a material having ferroelectric properties, and a gate electrode 33 disposed on the ferroelectric layer 21.

The semiconductor channel layer 10 may be a channel which includes a material having ferroelectric and semiconductor properties and provides a conductive path between the source electrode 31 and the drain electrode 32. The source electrode 31 and the drain electrode 32 may be made of a conductive material including a conductor. When a voltage is applied between the source electrode 31 and the drain electrode 32, polarization may occur in the semiconductor channel layer 10. When the source electrode 31 and the drain electrode 32 are spaced apart from and substantially coplanar with each other (as shown in FIG. 1), polarization of horizontal direction may occur in the semiconductor channel layer 10 between the source electrode 31 and the drain electrode 32.

In the context of this specification, “polarization” means a phenomenon in which negative and positive charges constitute dipole moments while positions thereof are separated in an electric field.

The ferroelectric layer 21 may include a material having ferroelectric properties. When a voltage is applied to the gate electrode 33, polarization may occur in the ferroelectric layer 21. Since the gate electrode 33 may be formed on the ferroelectric layer 21, polarization of vertical direction may occur in the ferroelectric layer 21 below the gate electrode 33. Since the polarization of vertical direction has electrical potential energy, the polarization of vertical direction also affects polarization of the semiconductor channel layer 10.

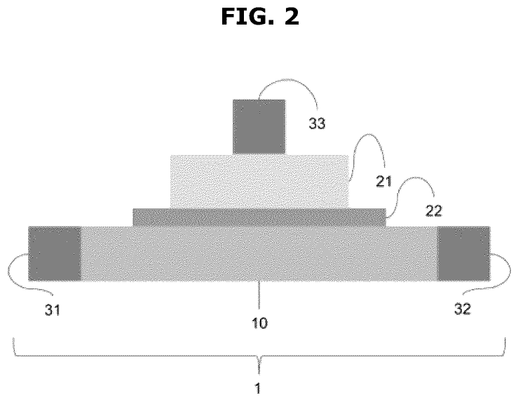

Meanwhile, FIG. 2 is a schematic diagram illustrating another example of a junction structure element according to an embodiment of the present invention.

Referring to FIG. 2, in one embodiment, a junction structure element 1 may further include an insulating layer 22 which is disposed between a semiconductor channel layer 10 and a ferroelectric layer 21 and has insulating properties.

The insulating layer 22 may be formed between the semiconductor channel layer 10 and the ferroelectric layer 21 to prevent a gate leakage current. Meanwhile, since an effect of electrical potential energy, which is generated due to a polarization phenomenon generated in the ferroelectric layer 21, on a polarization phenomenon in the semiconductor channel layer 10, should be maintained, a material and shape of the insulating layer 22 may be selected to perform such a function. In one embodiment, the insulating layer 22 may have a thickness of about 5 nm to 10 nm. In one embodiment, the insulating layer 22 may include h-BN.

Still referring to FIGS. 1 and 2, the semiconductor channel layer 10 and the ferroelectric layer 21 may each be made of at least one selected from materials having ferroelectric properties as described above. In one embodiment, the semiconductor channel layer and the ferroelectric layer may include at least one material each independently differently selected from the group consisting of graphanol, hydroxyl-functionalized graphene, halogen-decorated phosphorene, g-C₆N₈H, Bi—CH₂OH and two-dimensional perovskite including arsenic (As), antimony (Sb), bismuth (Bi), tellurium (Te), d1T-MoS₂, t-MoS₂, WS₂, WSe₂, WTe₂, BiN, SbN, BiP, α-In₂Se₃, GaN, GaSe, SiC, BN, AlN, ZnO, GeS, GeSe, SnS, SnSe, SiTE, GeTe, SnTE, PbTe, CrN, CrB₂, CrBr₃, CrI₃, GaTeCl, AgBiP₂Se₆, CuCrP₂S₆, CuCrP₂Se₆, CuVP₂S₆, CuVP₂Se₆, CuInP₂Se₆, CuInP₂S₆(CIPS), Sc₂CO₂, Bi₂O₂Se, Bi₂O₂Te, Bi₂O₂S, Ba₂PbCl₄. For example, the semiconductor channel layer 10 may include α-In₂Se₃ or SnS, and the ferroelectric layer 21 may include CIPS. In the context of the present specification, “CIPS” refers to CuInP₂S₆. In one embodiment, a band gap of the semiconductor channel layer 10 may be less than a band gap of the ferroelectric layer 21.

Still referring to FIGS. 1 and 2, in one embodiment, a voltage applied between the source electrode 31 and the drain electrode 32 may adjust a degree of polarization in the horizontal direction of the semiconductor channel layer 10. A voltage applied to the gate electrode 33 may adjust a degree of polarization in the vertical direction of the ferroelectric layer 21.

When such configurations and features are used, the junction structure element according to the embodiment of the present invention may be used as a memory element or a computing element.

In one embodiment, the junction structure element may be used as a reconfigurable logic element. In the context of the present specification, “reconfigurable logic element” refers to an element of which, after manufacturing, an internal logic structure can be changed by a user. In one embodiment, according to an increasing or decreasing state of a current applied between the source electrode 31 and the drain electrode 32 and an increasing or decreasing state of a current applied to the gate electrode 33, an increasing or decreasing state of a current conducted in the semiconductor channel layer 10 may be determined. As an example, in a case in which an increasing state of a current applied to the source electrode 31 or the gate electrode 33 is set to 1 and a decreasing state thereof is set to 0, when one state of two states is set to 1, a state output to the gate electrode 33 is set to 1, when both of two states are set to 0, a state output to the gate electrode 33 is set to be 0, when both of two states are 1, a state output to the gate electrode 33 is set to 1, or when one state of two states is 0, a state output to the gate electrode 33 is set to be 0, each OR/AND logic circuit may be implemented, and conversion between logic circuits can be performed without changing a manufacturing state of an element.

In one embodiment, the junction structure element may be used as a multi-state memory. In the context of this specification, “multi-state memory” refers to a memory that has the number of states that exceeds two unlike conventional memories which have only two states. In one embodiment, current conductivity of the semiconductor channel layer 10 may be determined according to a pulse of voltage applied between the source electrode 31 and the drain electrode 32 and a pulse of voltage applied to the gate electrode 33. As an example, vertical polarization by the gate electrode 33 may control electrical conductivity of the semiconductor channel layer 10, and horizontal polarization by the source electrode 31 and the drain electrode 32 may control Schottky barriers of junctions between the semiconductor channel layer 10 and the source and drain electrodes 31 and electrode 32.

In one embodiment, the semiconductor channel layer 10 may have a thickness of about 40 nm to 60 nm, and the ferroelectric layer 21 may have a thickness of about 60 nm to 100 nm.

The source electrode 31, the drain electrode 32, and the gate electrode 33 may be made of a conductive material. As an example, the source electrode 31, the drain electrode 32, and the gate electrode 33 may include a metal. In one embodiment, the source electrode 31, the drain electrode 32, and the gate electrode 33 may each include at least one material selected from the group consisting of titanium (Ti) and gold (Au).

As described above, polarization characteristics of the junction structure element according to the embodiment of the present invention can be stably adjusted, and thus the junction structure element can be applied as a memory or computing element.

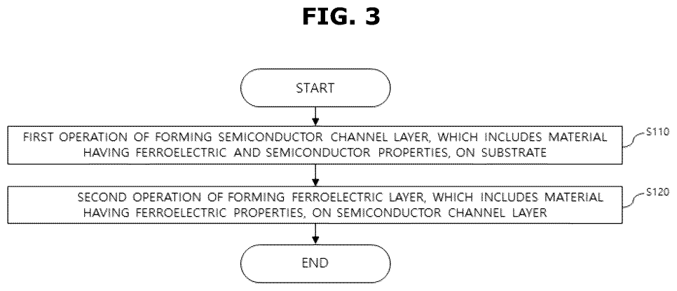

FIG. 3 is a flowchart illustrating a part of a method of manufacturing a junction structure element according to an embodiment of the present invention.

Referring to FIG. 3, the method of manufacturing a junction structure element according to the embodiment of the present invention may include the first operation S110 of forming a semiconductor channel layer, which includes a material having ferroelectric and semiconductor properties, on a substrate, and the second operation S120 of forming a ferroelectric layer, which includes a material having ferroelectric properties, on the semiconductor channel layer.

The first operation S110 is an operation of forming the semiconductor channel layer on the substrate, and the second operation S120 is an operation of forming the ferroelectric layer on the semiconductor channel layer to complete a junction structure. The semiconductor channel layer and the ferroelectric layer may have the same shapes and characteristics as or similar shapes and characteristics to those described in relation to the junction structure element according to the embodiment of the present invention.

The method of manufacturing a junction structure element according to the embodiment of the present invention does not exclude the inclusion of other additional processing operations. In one embodiment, the method of manufacturing a junction structure element may include an electrode forming operation of forming a source electrode and a drain electrode each in contact with the semiconductor channel layer and spaced apart from each other, and forming a gate electrode to be disposed on the ferroelectric layer. The electrode forming operation is an operation of forming the source electrode, the drain electrode, and the gate electrode on the semiconductor channel layer and the ferroelectric layer. The electrode forming operation may be performed as a single operation after the second operation is completed or may be performed stage by stage when each of the first operation and the second operation is completed.

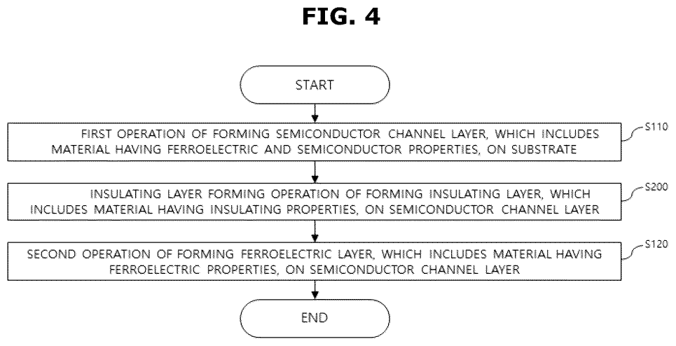

FIG. 4 is a flowchart illustrating a method of manufacturing a junction structure element according to another embodiment of the present invention.

Referring to FIG. 4, in one embodiment, the method of manufacturing a junction structure element according to the embodiment of the present invention may further include, after the first operation S110, the insulating layer forming operation S200 of forming an insulating layer, which includes a material having insulating properties, on the semiconductor channel layer. In this case, in the second operation S120, the ferroelectric layer may be formed on the insulating layer. The insulating layer may prevent a gate leakage current from the semiconductor channel layer to the ferroelectric layer. The insulating layer may have the same shape and features as or similar shape and features to that described in relation to the junction structure element according to the embodiment of the present invention.

The semiconductor channel layer, the ferroelectric layer, and the insulating layer may be made of the same material as or similar material to those described in relation to the junction structure element according to the embodiment of the present invention.

A forming method may be selected according to a material included in the semiconductor channel layer, the ferroelectric layer, and the insulating layer, and a shape to be processed. In one embodiment, the semiconductor channel layer, the ferroelectric layer, and the insulating layer may be formed through dry transferring.

As described above, in the method of manufacturing a junction structure element according to the embodiment of the present invention, it is possible to provide a process of implementing the junction structure element.

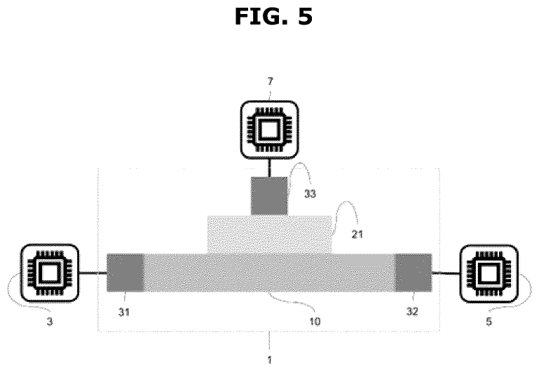

FIG. 5 is a diagram illustrating a configuration of a computing device according to an embodiment of the present invention.

Referring to FIG. 5, the computing device according to the embodiment of the present invention may include a junction structure element 1 including a semiconductor channel layer 10 which includes a material having ferroelectric and semiconductor properties, a source electrode 31 and a drain electrode 32 which are each in contact with the semiconductor channel layer 10 and are spaced apart from each other, a ferroelectric layer 21 which is disposed on the semiconductor channel layer 10 and includes a material having ferroelectric properties, and a gate electrode 33 disposed on the ferroelectric layer 21, an input unit 3 electrically connected to the source electrode, an output unit 5 electrically connected to the drain electrode, and a control unit 7 electrically connected to the gate electrode.

The junction structure element 1 and constituent members thereof may include the same materials and shapes as or similar materials and shapes to those described in relation to the junction structure element according to the embodiment of the present invention. In addition, the computing device may include one or more junction structure elements 1.

The input unit 3, the output unit 5, and the control unit 7 may transmit or receive electrical signals to or from the junction structure element 1, and thus the computing device may be a device that may perform computing mechanically, electrically, or electronically. When the computing device includes one or more junction structure elements 1 as described above, each junction structure element may be connected to the input unit 3, the output unit 5, and the control unit 7, and a connection method thereof may be a series method, a parallel method, or a combination thereof.

As described above, a junction structure element that can be used as a memory and/or a computing element may be applied to a computing device according to an embodiment of the present invention.

Hereinafter, embodiments of the present invention will be described in detail. However, the following embodiments are merely some embodiments of the present invention, and it should not be understood that the scope of the present invention is limited to the following embodiments.

Manufacturing of Junction Structure Element

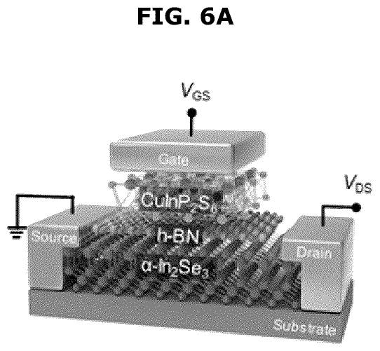

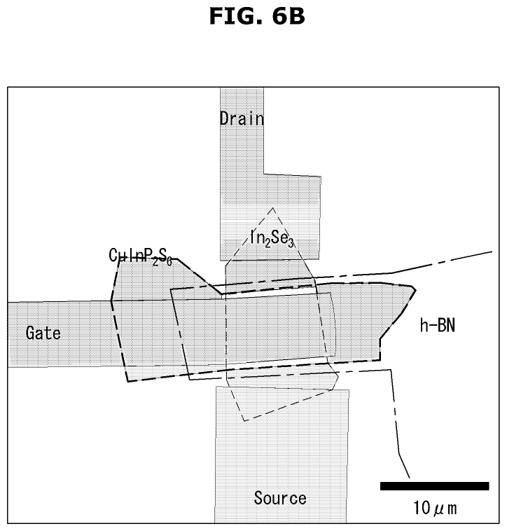

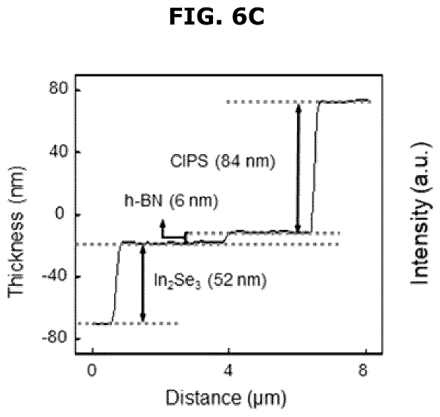

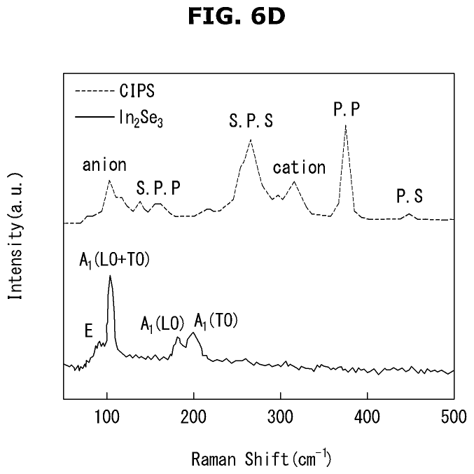

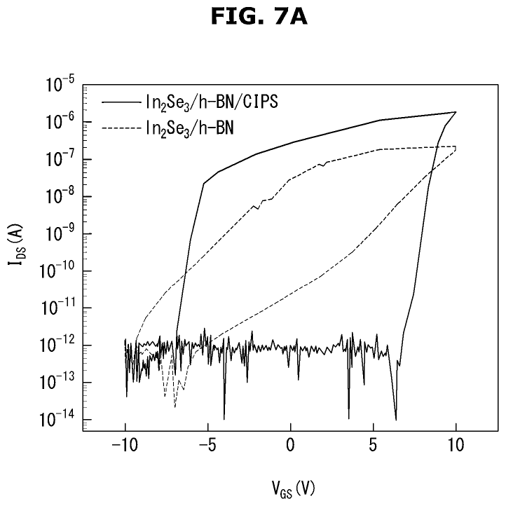

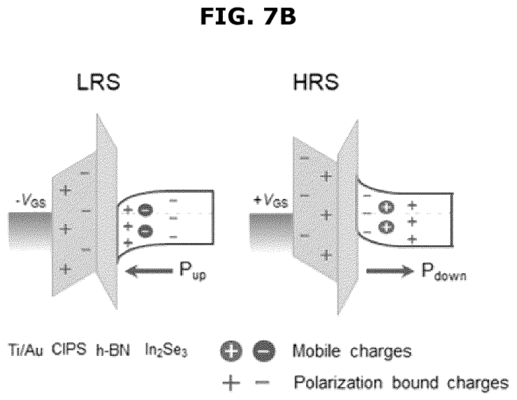

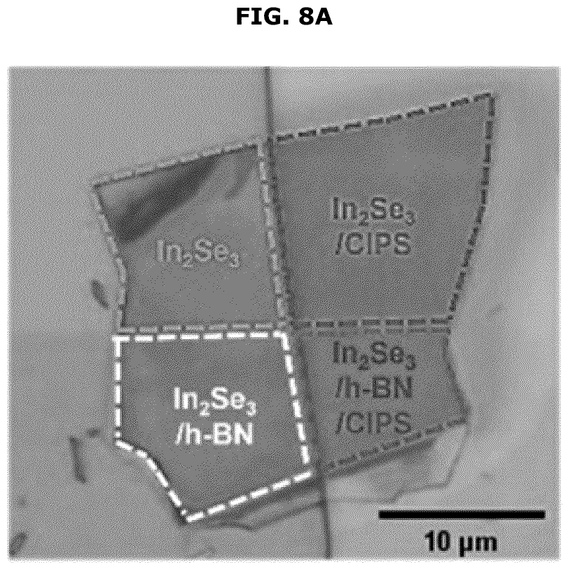

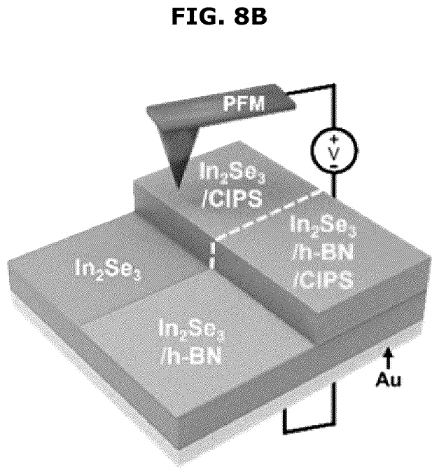

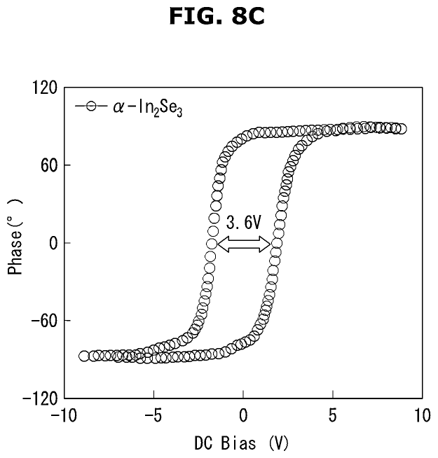

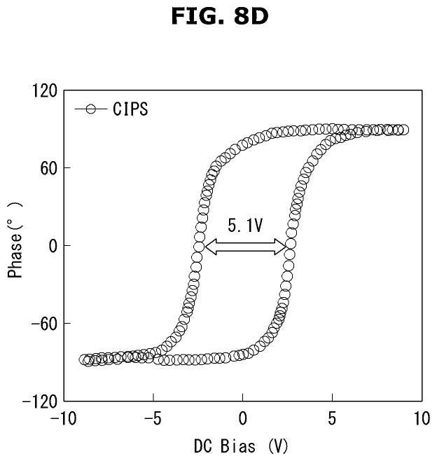

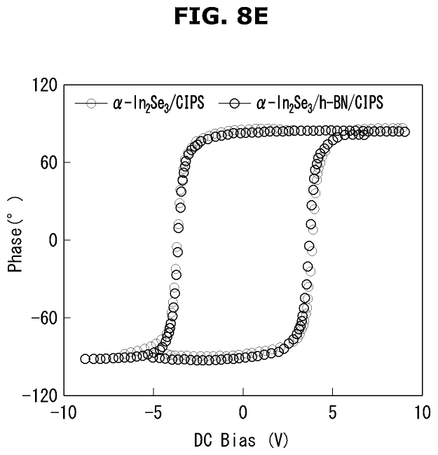

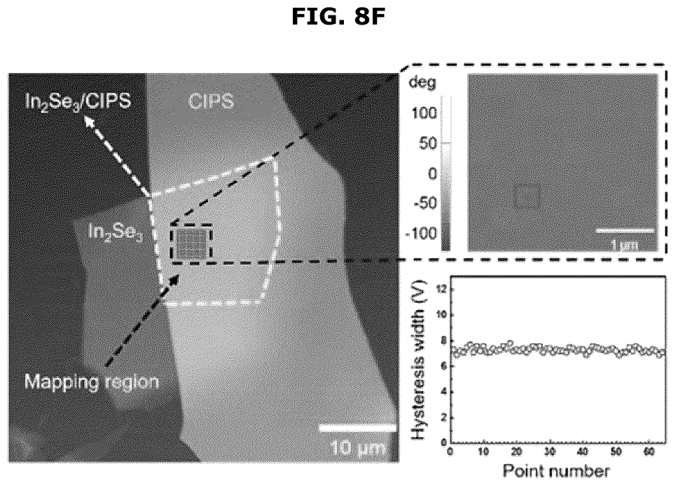

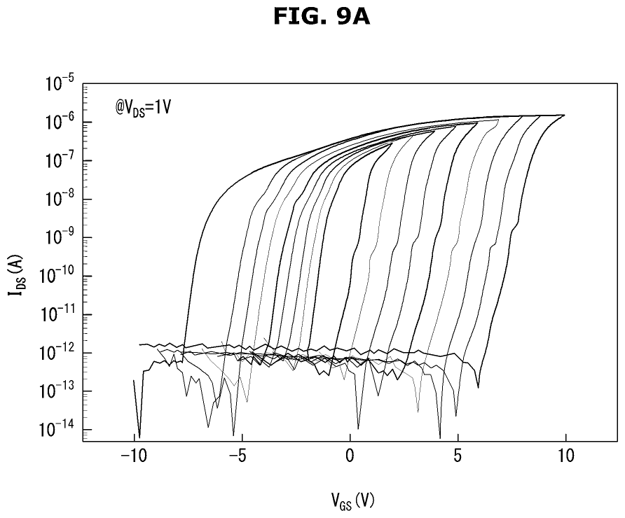

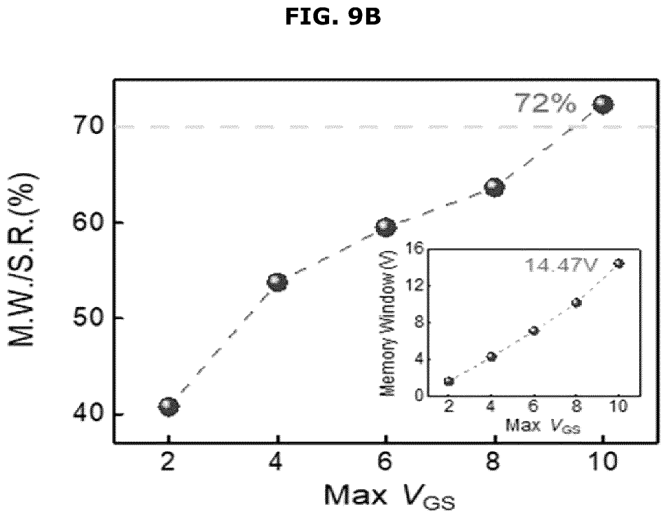

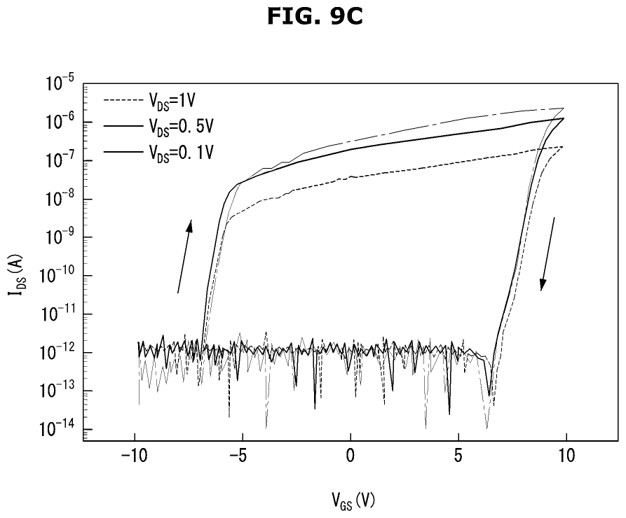

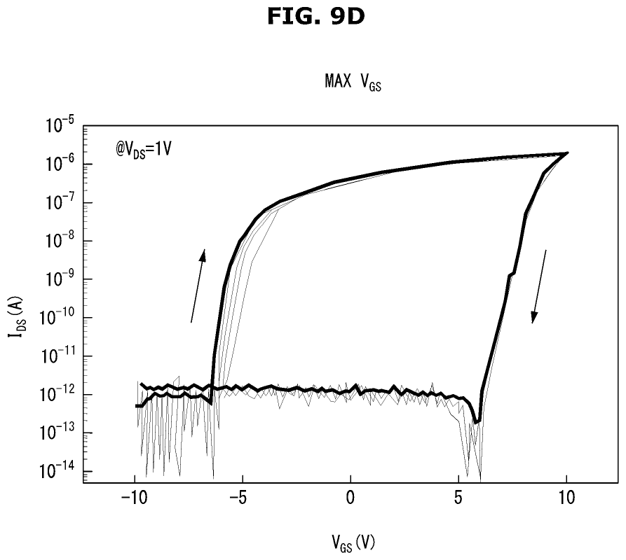

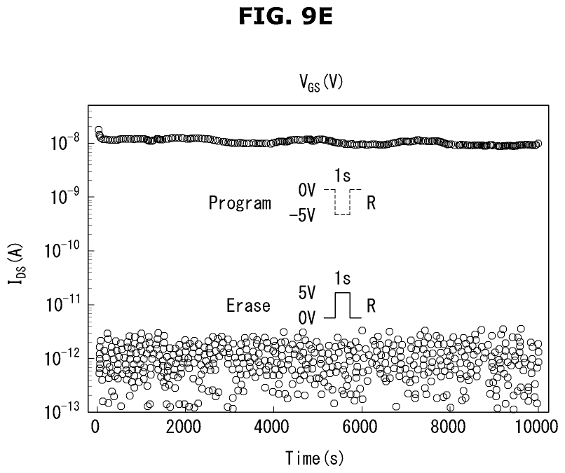

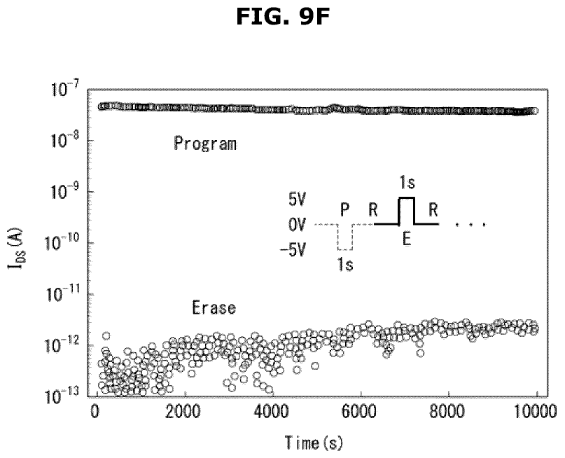

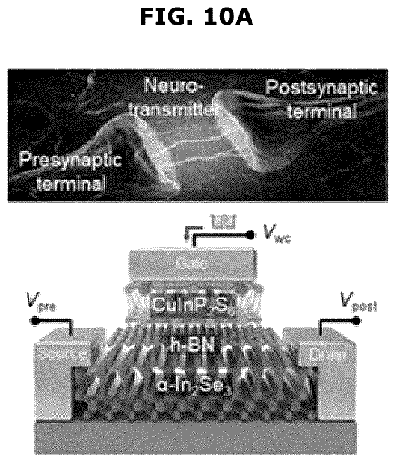

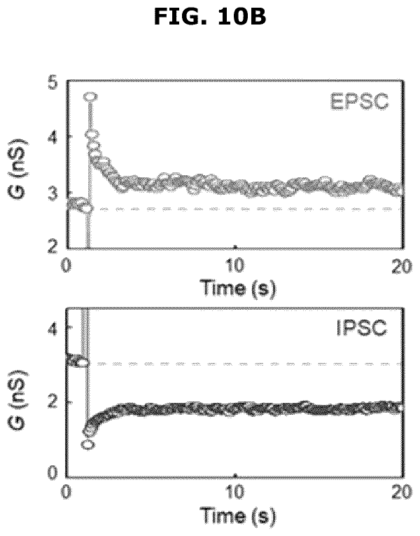

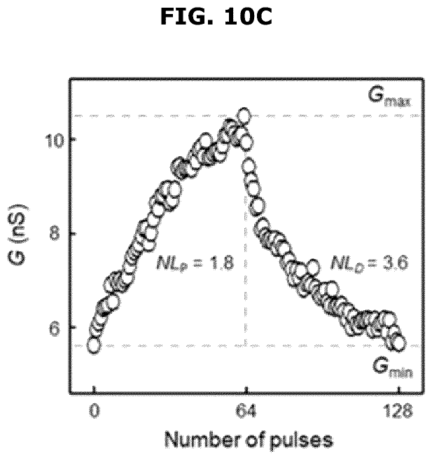

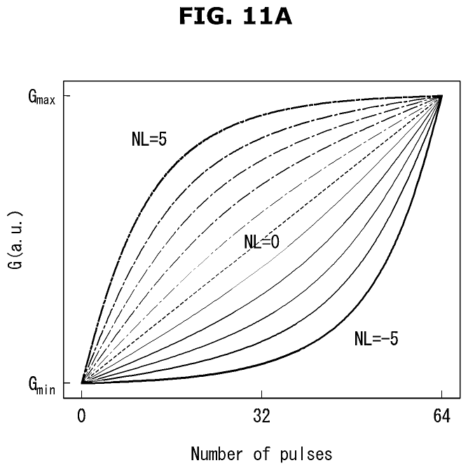

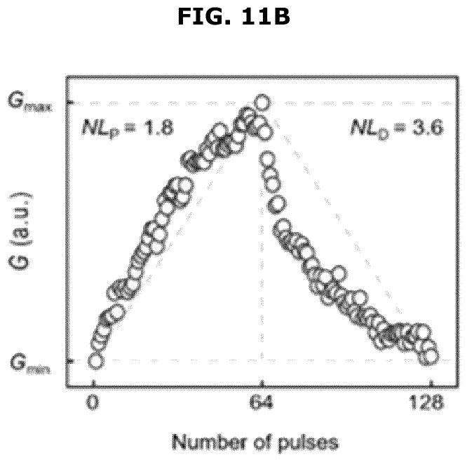

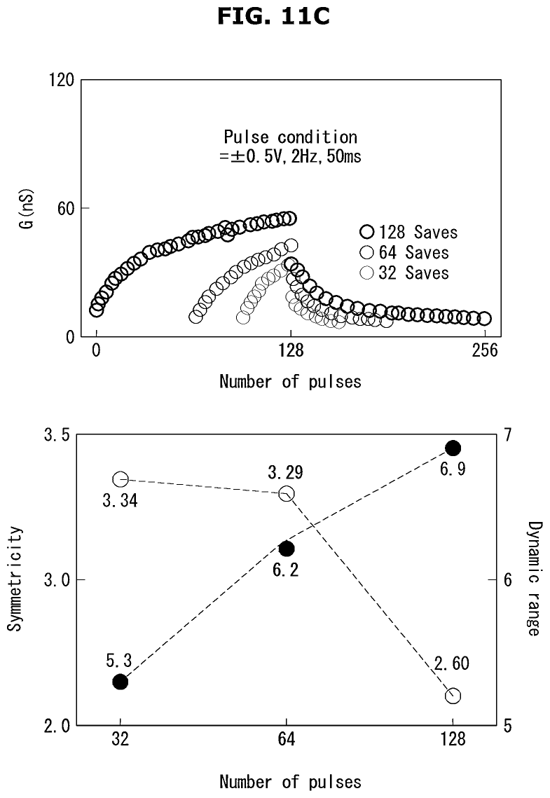

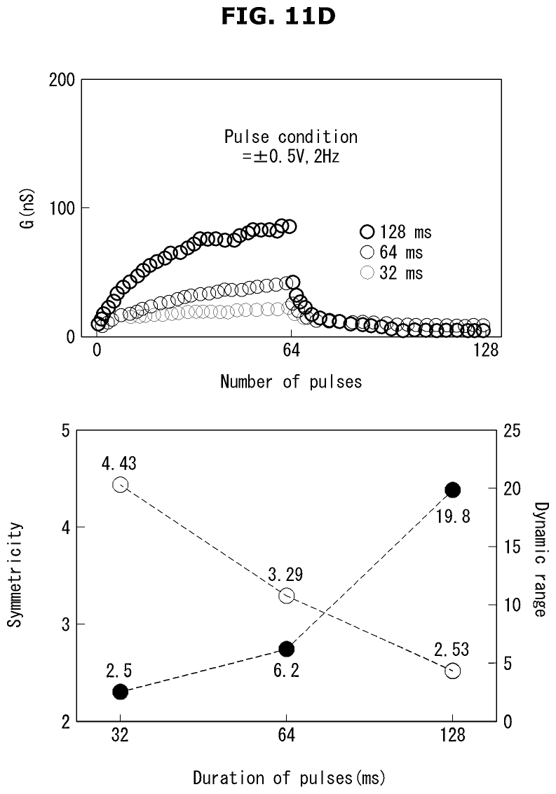

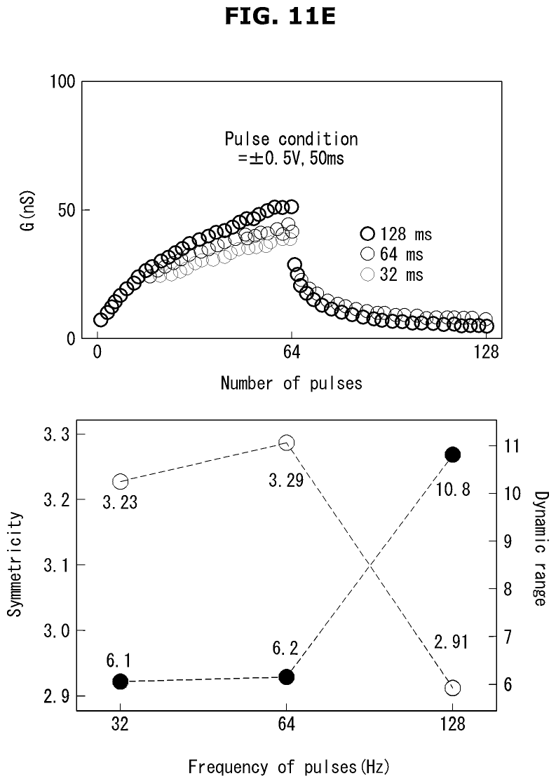

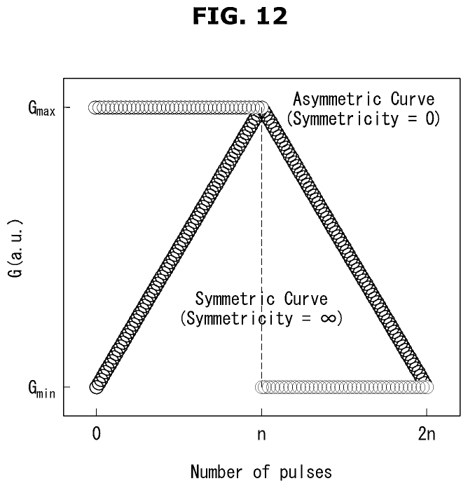

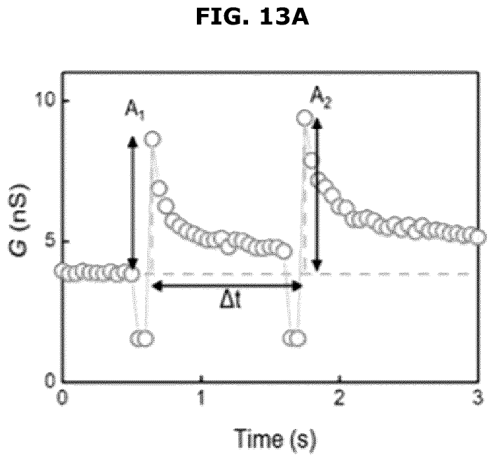

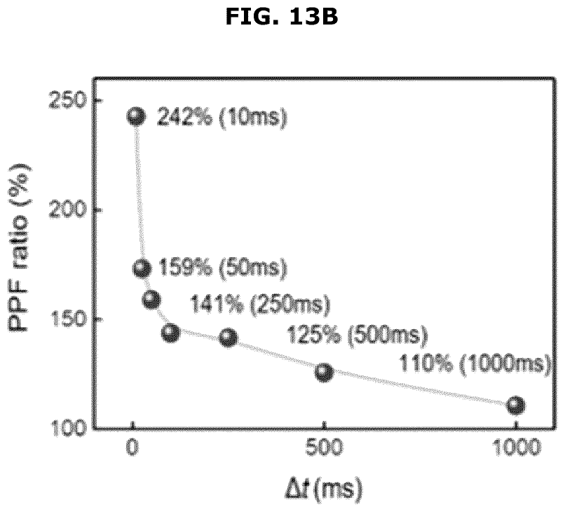

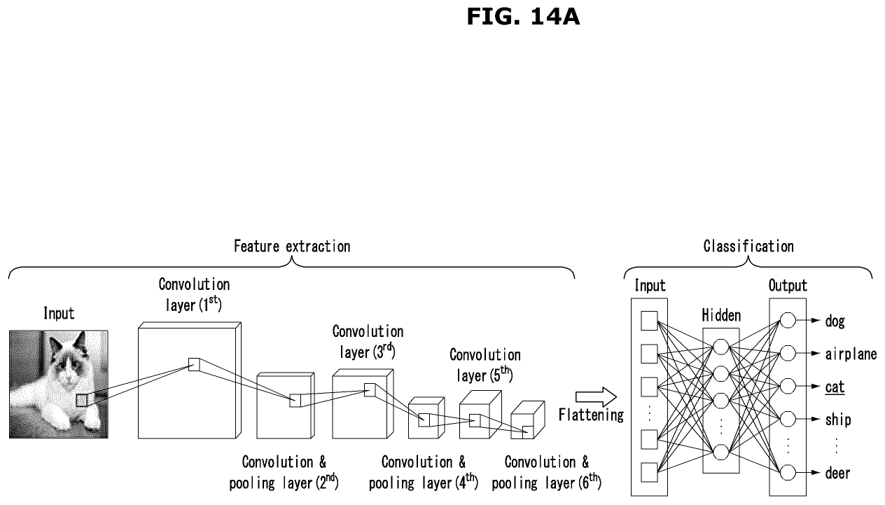

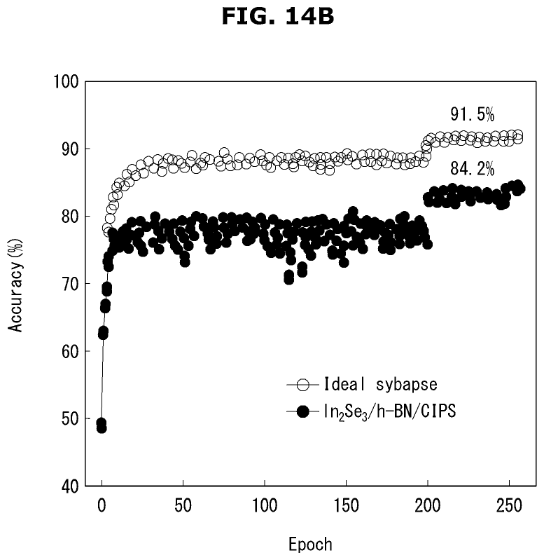

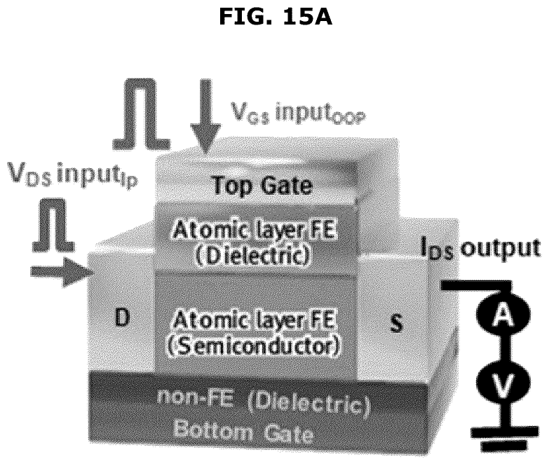

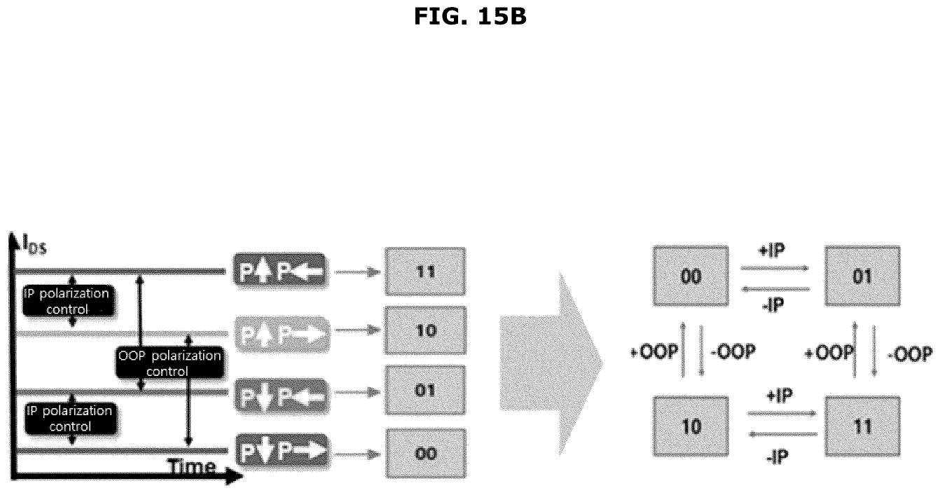

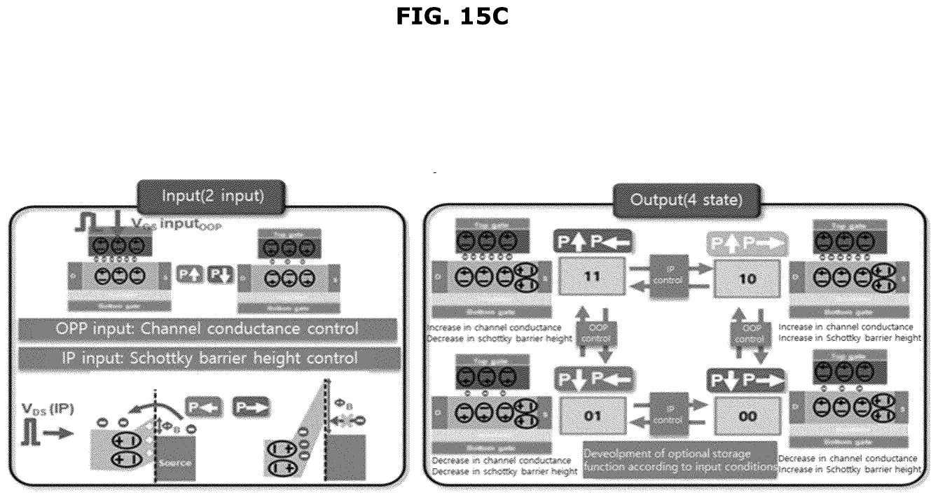

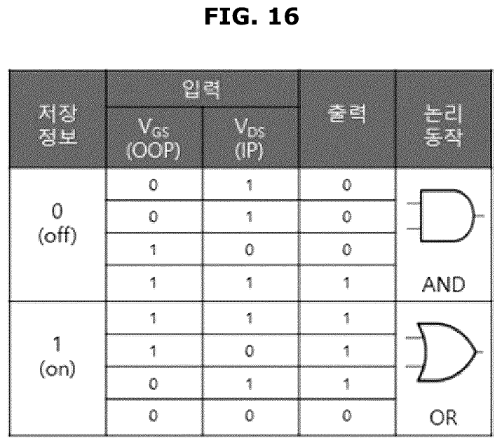

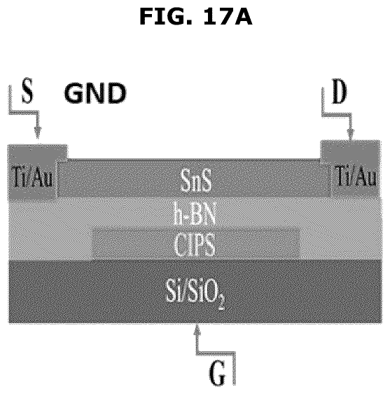

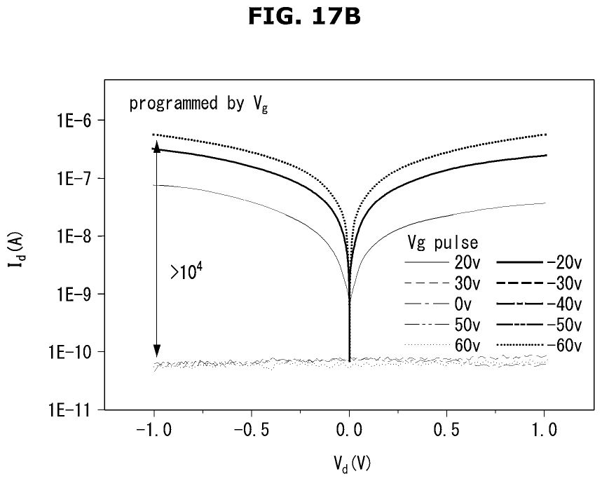

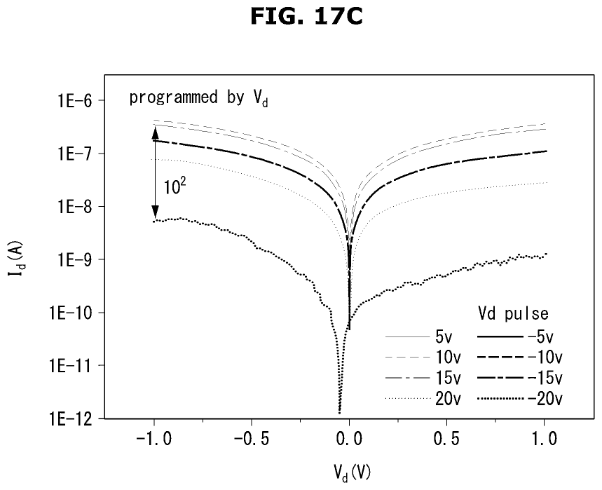

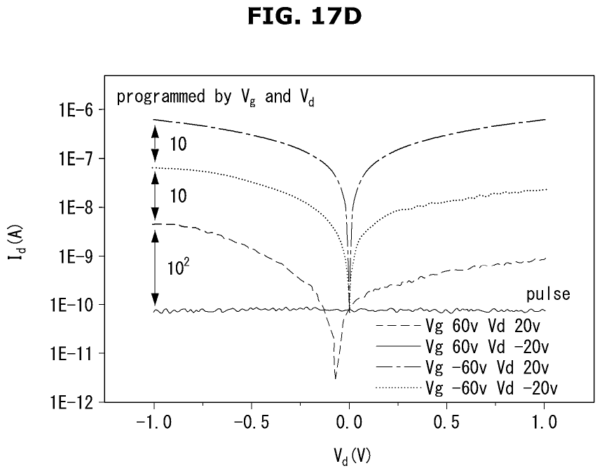

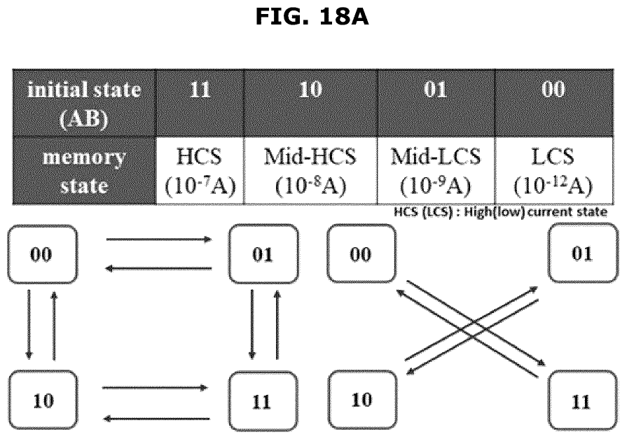

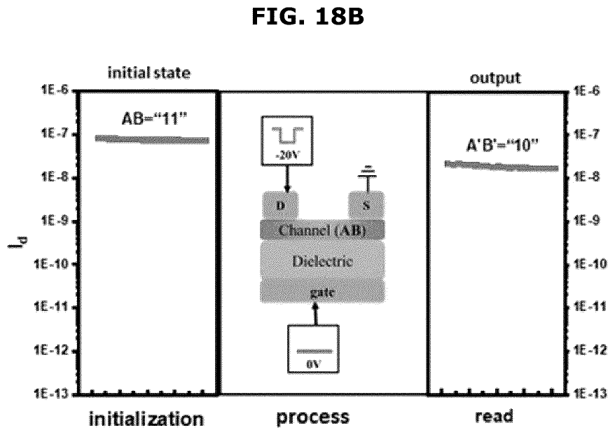

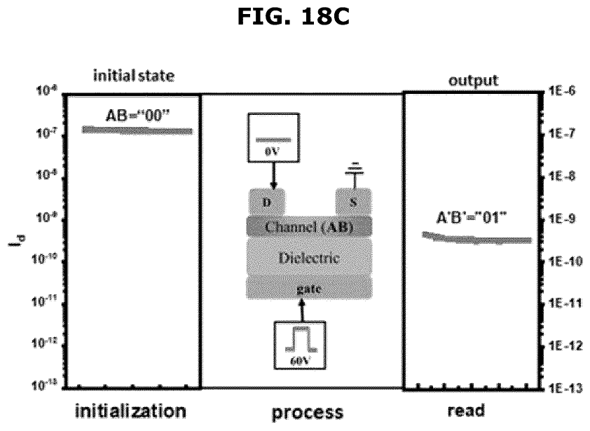

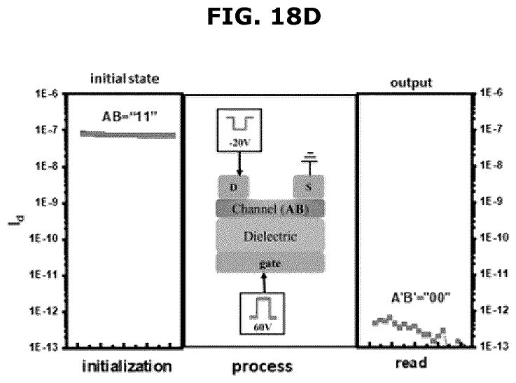

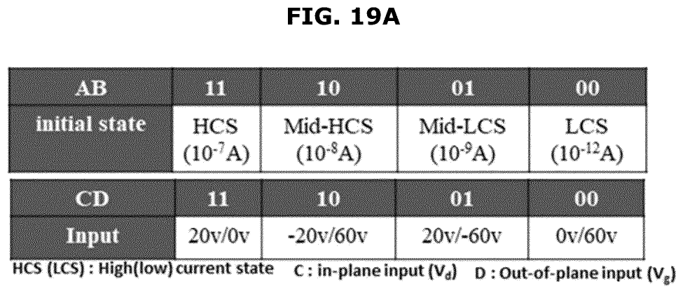

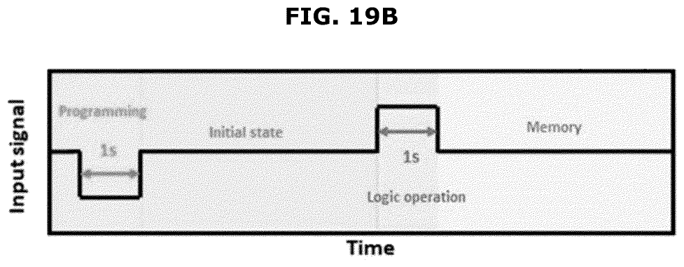

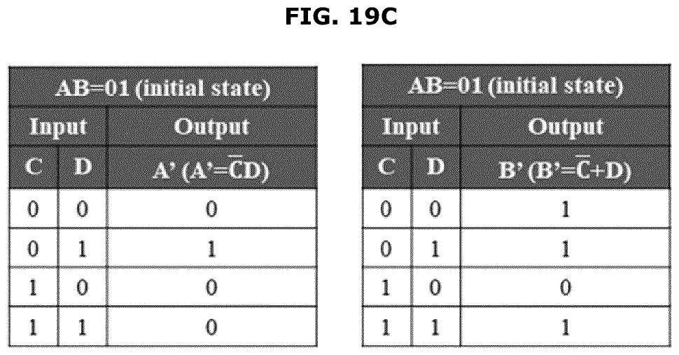

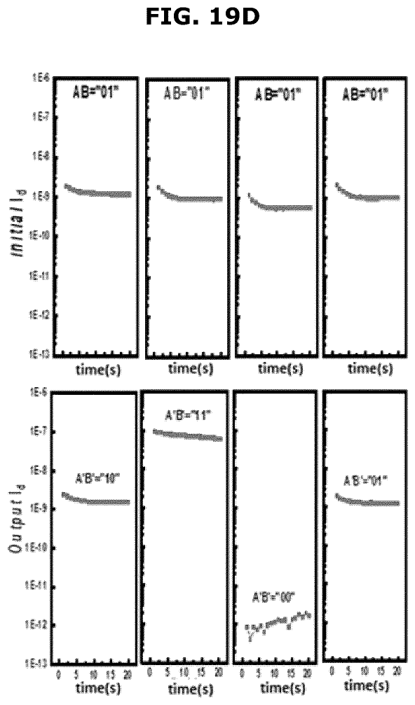

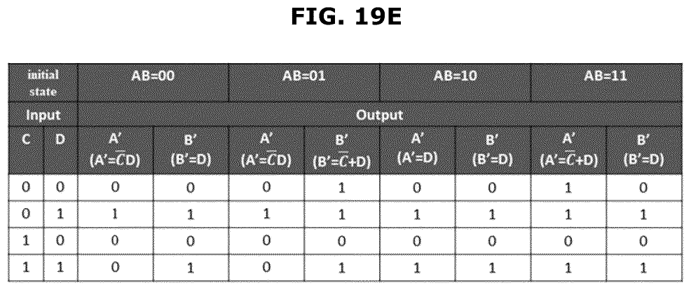

α-In₂Se₃, h-BN, and CIPS thin films were sequentially formed on a SiO₂/Si substrate using dry transferring to form a stacked junction structure. Then, a Ti (10 nm)/Au (80 nm) source electrode, drain electrode, and gate electrode on CIPS were formed. FIGS. 6A and 6B are a drawing and an image showing a manufactured element.

Characteristics of Junction Structure Element

As shown in FIG. 6A and FIG. 6B, A thickness of each thin film of a junction structure element was measured using an atomic force microscopy (AFM). FIG. 6C shows results of the measurement. Referring to FIG. 6C, thicknesses of the α-In₂Se₃, h-BN, and CIPS thin films are 52 nm, 6 nm, and 84 nm, respectively.

A material of each thin film was analyzed using a Raman spectrum. FIG. 6D shows results of the analysis. full line and dotted line in FIG. 6D are lines obtained by measuring α-In₂Se₃ and CIPS, respectively. Referring to FIG. 6D, it can be confirmed that the materials of the thin films are α-In₂Se₃ and CIPS.

Measurement of Element Characteristics and Energy Band Diagram According to Polarization State

full line and dotted line graphs in FIG. 7A are a transfer curve of the junction structure element according to Manufacturing Example and a transfer curve of an element using only one ferroelectric semiconductor material (Comparative Example), respectively. Both of two elements show n-characteristics and clockwise hysteresis, and Manufacturing Example shows a result in which a memory window is considerably widened as compared with Comparative Example. The result means that polarization of CIPS has improved a conduction behavior of a ferroelectric α-In₂Se₃ channel.

FIG. 7B is a schematic diagram for describing a principle, in which a memory window is widened through a ferroelectric material junction, through an energy band diagram. Unlike ferroelectric CIPS which has only polarization-bound charges, an α-In₂Se₃ ferroelectric semiconductor has two types of charges of polarization-bound charges and mobile charges due to ferroelectric properties and semiconductor properties. When a negative (or positive) voltage of a coercive voltage V_{c} or less (or more) is applied to a gate, polarization-bound charges of CIPS and α-In₂Se₃ are arranged in a polarization-up (down) state. As a result, downward (or upward) band bending occurs, and an accumulation (or depletion) phenomenon occurs on an α-In₂Se₃ channel surface, and thus a low (or high) resistance state is reached. Clockwise hysteresis is implemented through such a principle. Due to a mutual coupling effect, polarization-bound charges generated by dipoles of α-In₂Se₃ and CIPS being arranged in one direction by an external electric field maintain polarization for a longer time as compared with Comparative Example. Thus, the polarization-bound charges have a wide memory window and high endurance and retention.

Piezoelectric Force Microscopy (PFM) Measurement

In order to confirm ferroelectric properties of other stack structures, PFM measurement was performed. FIGS. 8A and 8B are an image of a stack structure and a schematic diagram of a setup of PFM measurement, respectively. FIG. 8C to FIG. 8E shows hysteresis loops in PFM images of α-In₂Se₃ (FIG. 8C), CIPS (FIG. 8D), and α-In₂Se₃/CIPS (FIG. 9E). As compared with α-In₂Se₃ (3.6 V) and CIPS (5.1 V), wider hysteresis (7.3 V) appears in an α-In₂Se₃/CIPS stack structure. This is due to dipole coupling occurring in polarized charges of two ferroelectric materials. Since h-BN has no ferroelectric properties, As shown in FIG. 8F, an α-In₂Se₃/h-BN/CIPS structure also exhibits the same hysteresis as the α-In₂Se₃/CIPS stack structure. However, h-BN serves as an insulator to suppress a gate leakage current.

Measurement of Memory Characteristics of Junction Structure Element

FIG. 9A to FIG. 9F shows measurement of memory characteristics of an α-In₂Se₃/h-BN/CIPS junction structure element at room temperature. FIG. 9A shows results in which transfer curve characteristics controlled with a gate electrode are measured by increasing a V_{GS} sweep range from ±2 V to ±10 V at V_{DS}=1 V.

A measured transfer curve shows that α-In₂Se₃/h-BN/CIPS exhibits an n-type behavior and clockwise hysteresis in addition to a wide memory window having a high on/off ratio of 106 and reaching 14.47 V at V_{GS} of 10 V or less. High memory characteristics are due to dipole coupling occurring in α-In₂Se₃ and CIPS described with reference to FIG. 8A to FIG. 8F.

FIG. 9B shows results in which a memory window and a ratio of the memory window (M.W.) to a sweep range (S.R.) are graphed according to a V_{GS} sweep range. The memory window increases linearly as the V_{GS} sweep range increases. When V_{GS} reaches up to 10 V, the memory window reaches 14.47 V, and M.W./S.R. reaches 72%. A ratio of M.W./S.R. is a characteristic value, which, since performance of Comparative Example is implemented with a different material, structure, and thickness, is expressed to compare characteristics thereof with results of the present invention.

Also, as shown in FIG. 9C, memory characteristics of the junction structure element according to an embodiment do not change significantly even under a drain bias. As shown in FIG. 9D, the junction structure element according to the embodiment stably operates without degradation even after dozens of consecutive cycles.

FIGS. 9E and 9F show memory retention and endurance characteristics of a memory using the junction structure element according to the embodiment when V_{DS}=1 V and program and erase pulses having a duration of 1 second and a magnitude of ±5 V are applied, respectively. A drain current was measured after the program and erase pulses were applied, and stable retention characteristics were measured in which a state in which a P/E current ratio was 10⁴ was maintained for 10⁴ seconds or more without degradation. In addition, endurance characteristics were also confirmed as characteristics in which two stable current states with a P/E current ratio of 10⁴ operated stably for 10³ cycles or more.

Comparison of Memory Element Characteristics

Characteristics of a memory element using a junction structure element according to an embodiment of the present invention was compared with characteristics of elements of other documents. Results thereof are shown in Table 1 below.

TABLE 1

| | | | | | | Present |
|---|---|---|---|---|---|---|
| | Ref. 1 | Ref. 2 | Ref. 3 | Ref. 4 | Ref. 5 | invention |
| Type | Fe-FET | Fe-FET | Fe-FET | FeS-FET | FeS-FET | Fe₂-FET |
| Ferro- | CIPS | PZT | P(VDF- | α-In₂Se₃ | α-In₂Se₃ | α-In₂Se₃ |
| electric | | | TrFE) | | | CIPS |
| Channel | MoS₂ | MoS₂ | MoSe₂ | α-In₂Se₃ | α-In₂Se₃ | α-In₂Se₃ |
| Gate | h-BN/ | PZT | P(VDF- | SiO₂ | Al₂O₃/ | h-BN/ |
| insulator | CIPS | | TrFE) | | h-BN | CIPS |
| On/off | >10⁷ | >10³ | >10⁵ | >10² | >10⁴ | >10⁶ |
| ratio | | | | | | |
| Retention | >10⁴ s | >10⁴ s | 2 × 10³ s | Not | 500 s | >10⁴ s |
| | | | | provided | | |
| Endurance | 300 | 100 | >10⁴ | Not | 500 | >10³ |
| | | | | provided | | |
| Memory | 104 V | 6 V | 30 V | 50 V | 6 V | 14.47 V |
| window | | | | | | |
| Sweep | ±80 V | ±8 V | ±35 V | ±45 V | ±8 V | ±10 V |
| range | | | | | | |
| M.W./S.R. | 65% | 38% | 43% | 56% | 38% | 72% |

Ref. 1: W. Huang, F. Wang, L. Yin, R. Cheng, Z. Wang, M. G. Sendeku, J. Wang, N. Li, Y. Yao, J. He, Adv. Mater. 2020, 32, 1908040.
Ref. 2: X.-W. Zhang, D. Xie, J.-L. Xu, Y.-L. Sun, X. Li, C. Zhang, R.-X. Dai, Y.-F. Zhao, X.-M. Li, X. Li, IEEE Electron Device Lett. 2015, 36, 784.
Ref. 3: X. Wang, C. Liu, Y. Chen, G. Wu, X. Yan, H. Huang, P. Wang, B. Tian, Z. Hong, Y. Wang, 2D Mater. 2017, 4, 025036.
Ref. 4: B. Tang, S. Hussain, R. Xu, Z. Cheng, J. Liao, Q. Chen, ACS Appl. Mater. Interfaces. 2020, 12, 24920
Ref. 5: S. Wang, L. Liu, L. Gan, H. Chen, X. Hou, Y. Ding, S. Ma, D. W. Zhang, P. Zhou, Nat. Commun. 2021, 12, 1

As compared with other ferroelectric-based memory elements, through dipole coupling implemented by a junction structure, in a relatively low sweep range (±10 V), high M.W./S.R. (72%) was implemented, and concurrently, a high on/off ratio (>106) and high retention (>10⁴ s) and endurance (>10³) characteristics were implemented.

Measurement of Synaptic Characteristics of Junction Structure Element

FIG. 10A is a schematic diagram of a junction structure element according to an embodiment of the present invention that imitates the operation of a biological synaptic element. When an external electric field stimulus is applied to a weight control terminal (WCT), partial polarization switching occurs to cause a potentiation/depression phenomenon of a synaptic weight occurs, and thus conductivity of a channel is controlled.

FIG. 10B shows results in which measuring postsynaptic current (PSC) responses are measured according to an excitatory and inhibitory pulse V_{wc}. For excitatory PSC (EPSC)/inhibitory PSC (IPSO) measurement, a pulse V_{wc} of ±5 V (duration of 100 ms) was applied to the WCT to measure conductance (G=I_{psc}/Vₚₒₛₜ) under a condition in which Vₚₒₛₜ is 1 V. After the pulse V_{wc} was applied, the conductance increased from 2.71 nS to 3.01 nS in the case of EPSC (ΔG of 10.0%) and decreased from 3.04 nS to 1.84 nS (ΔG of 65.2%) in the case of IPSO. In both of the two cases, the conductance did not return to the initial state for 20 seconds after the pulse V_{wc} was applied.

FIG. 10C shows results in which LTP/LTD characteristics related to long-term plasticity are measured by applying 64/64 excitatory and inhibitory pulses V_{wc} of ±0.5 V and 2 Hz (duration of 5 ms). When the 64 excitatory pulses V_{wc} were consecutively applied to the WCT, conductance level potentiation increased from 5.61 nS to 10.5 nS (nonlinearity (NL)=1.8). On the other hand, when the 64 inhibitory pulses V_{wc} were applied, conductance level depression decreased from 10.5 nS to 5.66 nS (NL=3.6). When consecutive electrical pulses are applied, dipoles of α-In₂Se₃ and CIPS are gradually switched by an applied electric field, resulting in a gradual change in conductance.

NLs of LTP/LTD Curves and LTP/LTD Curves Under Various Pulse Conditions

FIG. 11A shows NLs of LTP/LTD curves and changes in LTP/LTD curves under various conditions. The NLs of the LTP/LTD curves are obtained through Equation 1 below.

$$\begin{matrix}{G}_{LTP} = B ( 1 - {e}^{( - \frac{P}{{A}_{P}} )} ) + {G}_{min} \\ {G}_{LTD} = - B ( 1 - {e}^{( \frac{P - {P}_{max}}{{A}_{D}} )} ) + {G}_{max} \\ B = ( {G}_{max} - {G}_{min} ) / ( 1 - {e}^{\frac{- {P}_{max}}{{A}_{PD}}} )\end{matrix} \qquad [ Equation 1 ]$$

In this case, G_{LTP} and G_{LTD} are conductance values of the LTP/LTD curves. Gₘₐₓ, Gₘᵢₙ, and P denote maximum conductance, minimum conductance, and the number of applied pulses, respectively. A is NL, and B is a fitting constant for normalizing a conductance range.

An NL value may be obtained through a value A listed in a table provided through DNN+NeuroSim. As shown in FIG. 11B, NL values of the fitted LTP/LTD curves are 1.8 and 3.6, respectively.

Additionally, the LTP/LTD curves under various pulse conditions (number of pulses, duration, and frequency) were confirmed as shown in FIGS. 11C and 11E, and a dynamic range (DR) (Gₘₐₓ/Gₘᵢₙ), and symmetricity were extracted.

When the number of pulses increased from 32 to 128, as shown in FIG. 11C, a DR value increased from 5.3 to 6.9, and symmetricity decreased from 3.34 to 2.6. When the total electrical energy applied increases, the number of switched dipoles increases, resulting in a large change in conductance. As shown in FIGS. 11D and 11E, similar results in which a large change in duration and a frequency of pulses is resulted were also confirmed. When a stronger or faster pulse is applied, the total electrical energy applied during the same period increases, which eventually leads to a large change in conductance.

Analysis of Symmetricity in LTP/LTD Curves

As Shown FIG. 12, Symmetricity is obtained through Equation 2 below.

$$Symmetricity = \frac{1}{Symmetric error} \qquad [ Equation 2 ]$$

$$Symmetric error = {\sum }_{k = 1}^{k = n} \frac{{( {G}_{N} ( k ) - {G}_{N} ( 2 n - k ) )}^{2}}{n} = {\sum }_{k = 1}^{k = n} \frac{{( ( G ( k ) - {G}_{min} ) - ( G ( 2 n - k ) - {G}_{min} ) )}^{2}}{{n ( {G}_{max} - {G}_{min} )}^{2}}$$

$$= {\sum }_{k = 1}^{k = n} \frac{{( G ( k ) - G ( 2 n - k ) )}^{2}}{{n ( {G}_{max} - {G}_{min} )}^{2}} , where {G}_{N} ( k ) = \frac{G ( k ) - {G}_{min}}{{G}_{max} - {G}_{min}}$$

In this case, GN, Gₘₐₓ, and Gₘᵢₙ are normalized, maximum, and minimum conductances, respectively.

First Peak to Second Peak (PPF) Characteristics of Junction Structure Synaptic Element

A PPF related to short-term plasticity was measured as shown FIGS. 13A and 13B. When two consecutive pulses (duration of 100 ms and −0.5 V) are applied at an interval of Δt, a Δt-dependent facilitation behavior may be confirmed at a PSC through a PPF ratio A2/A1. The PPF ratio increased exponentially as Δt decreased (when Δt=1,000 ms, the PPF ratio was 110%, and when Δt=10 ms, the PPF ratio was 242%). This means that the PPF characteristics of a synaptic element of the present invention are similar to those of biological synapses.

Convolution Neural Network (CNN) and Image Recognition Accuracy

Based on a synapse element using a junction structure element according to an embodiment of the present invention, availability as a hardware neural network was presented using a “DNN+NeuroSlM” simulator.

A CNN was used as an artificial neural network simulator, and the Canadian Institute for Advanced Research-10 (CIFAR-10) image dataset was used as training (50,000 images) and inference (10,000 images) images.

FIG. 14A shows a schematic diagram of a CNN including six convolution layers for extracting six features and two fully connected (FC) layers for classification. In order to measure image recognition accuracy of a junction structure element, 50,000 training tasks and 10,000 inference tasks per epoch were performed, and as a result, as shown FIG. 14B, an accuracy of 84.2% was measured.

The operation of the CNN is as follows. Input image data includes 32×32 pixels and three red, green, and blue (RGB) channels, and a value of each element refers to a voltage value. In a first layer of the CNN, for a convolution process, a window including 3×3 kernel synaptic weights includes 128 depths with an interval of 1 according to an image pixel (that is, input voltage value×kernel synaptic weight=current value). After such a process, a data size is reduced. In order to prevent the reduction in data size, a “zero padding” process is performed to add a value of 0 to the outside of data.

Through convolution, a feature map is generated and is activated through a ReLu activation function. In such a process, a current value is converted into a voltage value.

An output value of the first layer is transmitted to a second layer, and a higher-level image feature is extracted through a similar process. A “pooling” process is added to augment a feature extracted during a process. A 3×3 pooling window having the same size as a kernel is used, and a max pooling method of extracting the highest element value within a window range is applied. Since the pooling process is applied, a size of output data is reduced as compared with input data.

In the present invention, the pooling process was optionally applied in second, fourth, and sixth layers. Such a process (convolution/convolution and max pooling) was repeated more than twice and an operation of a kernel window were sequentially increased to 128, 256, and 512. When data passed through 6 layers for feature extraction, six convolutions and three max pooling processes were performed. The form of a final output value was formed as a voltage value in the form of a 4×4×512 array. An output value was flattened into the form of a 1×8,192 array so as to be transmitted to an FC input layer later. A classification drawing of FIG. 14A shows the form of FC layers for image classification. The FC layer includes 8,192 input neurons, 1,024 hidden neurons (seventh layer), and 10 output neurons (eighth layer). In this case, an input layer was not included in counting the number of layers. All neurons in each layer were fully connected to neurons in a previous layer by synapses.

In a hidden layer (seventh layer), the sum of weighted input values (voltage value×synaptic weight) was obtained through a ReLu function and converted into an output voltage value. An output value of the seventh layer is transmitted as an input value of the eighth layer. A similar process was performed in the eighth layer and was performed through a softmax function. After a final output of the eighth layer was compared with a data set, a convolutional kernel and an FC synaptic weight were updated through a backpropagation algorithm (that is, a training task).

Multi-State Memory

FIG. 15A to FIG. 15C illustrates an operating principle and an operating method of a multi-state memory which is one of junction structure elements according to an embodiment of the present invention. FIG. 15A is a schematic diagram of a junction structure element according to an embodiment of the present invention. In a junction structure formed by bonding a semiconductor channel layer and a ferroelectric layer, types of settable polarization include IP polarization (horizontal polarization) and OOP polarization (vertical polarization). As shown in FIG. 15C, the OOP polarization is controlled through a voltage pulse input through a gate to control channel conductance, and the IP polarization is controlled through a voltage pulse applied to a source-drain to accumulate mobile electrons/holes in a Schottky barrier according to a polarization direction thereof and control the Schottky barrier. As a result, as shown in FIG. 15B, four current states (that is, memory states) may be implemented through OOP/IP polarization control, and conversion to each memory state may be controlled through rearrangement of a polarization direction. Thus, a possibility of implementing a multi-state memory through diversification of polarization control conditions through a junction of ferroelectrics is presented.

Reconfigurable Circuit

FIG. 15A and FIG. 16 illustrates a method of implementing a reconfigurable logic (or logic-in-memory (LiM) element in a junction structure element according to an embodiment of the present invention.

An element structure having two inputs (OOP/IP polarization control) is implemented through a structure as shown in FIG. 15A, and as shown in a logic table of FIG. 16, a state in which a current of an element is increased due to polarization arranged by each input is set to 1, and a state in which a current of the element is decreased is set to 0. In a case in which output current value of an element is set, when an output current range in a state in which both of two input values are 1 is set to 1 and an output range in a state which both of two input values are 0 is set to 0, a possibility of implementing a reconfigurable logic element in which an AND/OR operation is implemented in one element according to existing storage information stored in the element and two input conditions is presented. Such an element operation has characteristics of “logic-in-memory” because, in one element, a memory function may be performed and a logic circuit function may be performed according to an input value at the same time. This not only presents a possibility of a next-generation data processing structure that can solve a data bottleneck phenomenon that could not be solved in the existing von-Neumann-based data processing structure but also increases a possibility of improving element integration due to multifunctional element characteristics. In addition, a possibility of implementing other logic operation functions (NOR, NAND, NOT, XOR, XNOR, and the like) is presented according to a circuit and logic configuration.

Characteristics of SnS/h-BN/CIPS Structure Element

FIG. 17A to FIG. 17D illustrates a structure and characteristics of an element including SnS, which is a two-dimensional ferroelectric material, as a channel and having a junction structure between h-BN and CIPS. SnS is a two-dimensional ferroelectric semiconductor of which IP polarization characteristics are controllable. In a structure shown in FIG. 17A, polarizations of SnS and CIPS were controlled by a drain voltage and a gate voltage, respectively. FIGS. 17B, 17C, and 17C show output curves of a junction element controlled by a gate voltage, a drain voltage, and gate and drain voltages, respectively. FIG. 17B shows a current difference of 10⁴ or more according to a polarization state when polarization of CIPS is controlled by the gate voltage. FIG. 17C shows a current difference of 10² or more according to a polarization state when polarization of SnS is controlled by the drain voltage. Finally, in FIG. 17D, when polarization states of SnS and CIPS were controlled using the gate voltage and the drain voltage at the same time, four multi-memory states were implemented due to a current difference of about 10 to 10² for each polarization state.

SnS/h-BN/CIPS Multi-State Memory Characteristics and Operating Principle

FIG. 18A to FIG. 18D shows multi-state memory operation characteristics of a SnS/h-BN/CIPS junction structure element.

A table of FIG. 18A shows current values of respective memory states implemented through IP/OOP polarization control. As shown in FIG. 17, the current values of the respective memory states have a current value difference of 10 to 10² or more. Schematic diagrams below the table are a schematic diagram showing that each memory state is convertible into another memory state through an input value. FIGS. 18B, 18C, and 18D show experimental results of memory state conversion through an input value. FIG. 18B shows that an initial memory state (AB=“11”) is converted into another memory state (A′B′=“10”) through IP polarization control using an IP input value (input drain voltage of −20 V). FIG. 18C shows that an initial memory state (AB=“00”) is converted into another memory state (A′B′=“01”) through OOP polarization control using an OOP input value (input gate voltage of 60 V). FIG. 18D shows that an initial memory state (AB=“11”) is converted into another memory state (A′B′=“00”) through IP/OOP polarization control using IP/OOP input values (input drain voltage of −20 V and an input gate voltage of 60 V) so that multi-state memory implementation and conversion to each memory state are possible

SnS/h-BN/CIPS Reconfigurable Logic Characteristics

FIG. 19A to FIG. 19E shows results of implementing a logic operation for each memory state.

FIG. 19A shows a current value for each memory initial state AB and voltage conditions of an input value CD required to implement a logic operation. FIG. 19B shows a process of implementing a logic operation of a memory element.

In a programming process, an initial state is set and stored through IP/OOP input (initial state section). Then, other logic operations are implemented according to the stored initial state AB. In a logic operation section, polarization is controlled according to an IP/OOP input value CD to perform conversion to another memory state, thereby implementing the logic operation and storing result values of the implemented logic operation (memory section). FIGS. 19C and 19D show a logic table of output values A′ and B′ according to input values and experimental result values when the initial state AB=“01.” A 2-bit memory operation was implemented through development of four multi-state memories to implement an element performing two logic operations in a parallel manner through two output values A′ and B. In this case, the output value B′ (=C+D) in the initial state AB of “01” implements an IMP logic operation. Graphs of FIG. 19D show a storage state current value of the initial state AB and a storage state current value of an output state A′B′ when a polarization state is changed due to input of the input value CD to change a memory state. FIG. 19E shows the output state A′B′ according to the input value CD for each initial state AB of each memory. This shows that various logic operation output values can be implemented for each initial state of each memory. When an additional memory state is implemented through the development of an element structure in the future, more diverse logic operation execution functions can be implemented.

Polarization characteristics of a junction structure element according to embodiments of the present invention can be stably adjusted, and thus the junction structure element can be applied as a memory or computing element.

In a method of manufacturing a junction structure element according to an embodiment of the present invention, it is possible to provide a process of implementing the junction structure element.

A junction structure element usable as a memory and/or a computing element can be applied to a computing device according to embodiments of the present invention.

Although the present invention has been described with reference to the exemplary embodiments, it will be understood by those skilled in the art that various modifications and changes can be made in the present invention without departing from the spirit and scope of the present invention as defined in the appended claims.

What is claimed is:

1. A junction structure element comprising:
a semiconductor channel layer which includes a material having ferroelectric and semiconductor properties;
a source electrode and a drain electrode which are each in contact with the semiconductor channel layer and are spaced apart from each other;
a ferroelectric layer which is formed on the semiconductor channel layer and includes a material having ferroelectric properties; and
a gate electrode disposed on the ferroelectric layer.

2. The junction structure element of claim 1, further comprising an insulating layer which is disposed between the semiconductor channel layer and the ferroelectric layer and includes a material having insulating properties.

3. The junction structure element of claim 2, wherein the insulating layer has a thickness of 5 nm to 10 nm.

4. The junction structure element of claim 2, wherein the insulating layer includes h-BN.

5. The junction structure element of claim 1, wherein the semiconductor channel layer and the ferroelectric layer include at least one material each independently differently selected from the group consisting of graphanol, hydroxyl-functionalized graphene, halogen-decorated phosphorene, g-C₆N₈H, Bi—CH₂OH and two-dimensional perovskite including arsenic (As), antimony (Sb), bismuth (Bi), tellurium (Te), d1T-MoS₂, t-MoS₂, WS₂, WSe₂, WTe₂, BiN, SbN, BiP, α-In₂Se₃, GaN, GaSe, SiC, BN, AlN, ZnO, GeS, GeSe, SnS, SnSe, SiTE, GeTe, SnTE, PbTe, CrN, CrB₂, CrBr₃, CrI₃, GaTeCl, AgBiP₂Se₆, CuCrP₂S₆, CuCrP₂Se₆, CuVP₂S₆, CuVP₂Se₆, CuInP₂Se₆, CuInP₂S₆(CIPS), Sc₂CO₂, Bi₂O₂Se, Bi₂O₂Te, Bi₂O₂S, Ba₂PbCl₄.

6. The junction structure element of claim 5, wherein:
the semiconductor channel layer includes α-In₂Se₃ or SnS; and
the ferroelectric layer includes CIPS.

7. The junction structure element of claim 1, wherein:
a voltage applied between the source electrode and the drain electrode adjusts a degree of polarization in the horizontal direction of the semiconductor channel layer; and
a voltage applied to the gate electrode adjusts a degree of polarization in the vertical direction of the ferroelectric layer.

8. The junction structure element of claim 7, wherein an increasing or decreasing state of a current conducted in the semiconductor channel layer is determined according to an increasing or decreasing state of a current applied between the source electrode and the drain electrode and an increasing or decreasing state of a current applied to the gate electrode.

9. The junction structure element of claim 7, wherein current conductivity of the semiconductor channel layer is determined according to a pulse of the voltage applied between the source electrode and the drain electrode and a pulse of the voltage applied to the gate electrode.

10. The junction structure element of claim 1, wherein:
the semiconductor channel layer has a thickness of 40 nm to 60 nm; and
the ferroelectric layer has a thickness of 60 nm to 100 nm.

11. The junction structure element of claim 1, wherein the source electrode, the drain, and the gate electrode each include at least one material selected from the group consisting of titanium (Ti) and gold (Au).

12. A method of manufacturing a junction structure element, the method comprising:
a first operation of forming a semiconductor channel layer, which includes a material having ferroelectric and semiconductor properties, on a substrate;
a second operation of forming a ferroelectric layer, which includes a material having ferroelectric properties, on the semiconductor channel layer; and
an electrode forming operation of forming a source electrode and a drain electrode each in contact with the semiconductor channel layer and spaced apart from each other, and forming a gate electrode to be disposed on the ferroelectric layer.

13. The method of claim 12, further comprising, after the first operation, an insulating layer forming operation of forming an insulating layer, which includes a material having insulating properties, on the semiconductor channel layer,
wherein, in the second operation, the ferroelectric layer is formed on the insulating layer.

14. The method of claim 13, wherein the semiconductor channel layer, the insulating layer, and the ferroelectric layer are formed through dry transferring.
